(19) United States
(12) Patent Application Publication
(10) Pub. No.: US 2012/0280223 A1
(43) Pub. Date: Nov. 8, 2012

(54) OXIDE SEMICONDUCTOR DEVICES, METHODS OF MANUFACTURING OXIDE SEMICONDUCTOR DEVICES AND DISPLAY DEVICES HAVING OXIDE SEMICONDUCTOR DEVICES

(75) Inventors: Jeong-Hwan KIM, Yongin-si (KR); Seong-Min WANG, Yongin-si (KR); Joo-Sun YOON, Yongin-si (KR)

(73) Assignee: SAMSUNG MOBILE DISPLAY CO., LTD., Yongin-si (KR)

(21) Appl. No.: 13/296,609

(22) Filed: Nov. 15, 2011

(30) Foreign Application Priority Data
May 3, 2011 (KR) 10-2011-0041805

(51) Int. Cl. H01L 29/786; H01L 21/336

(52) U.S. Cl. 257/43; 438/158; 257/E29.273; 257/E21.412

(57) ABSTRACT

An oxide semiconductor device may include a gate electrode formed on a substrate, and a gate insulation layer formed on the substrate to cover the gate electrode. A channel protection structure may be disposed on the gate insulation layer to expose a portion of the gate insulation layer. A source electrode may be located on a first portion of the channel protection structure. A drain electrode may be disposed on a second portion of the channel protection structure. An active pattern may be positioned on the exposed portion of the gate insulation layer, the source electrode, and the drain electrode.

### CROSS REFERENCE TO RELATED APPLICATION

This application claims priority from and the benefit of Korean Patent Application No. 10-2011-0041805, filed on May 3, 2011, the contents of which are herein incorporated by reference in their entirety.

### BACKGROUND

1. Field

Example embodiments relate to oxide semiconductor devices, methods of manufacturing oxide semiconductor devices, and display devices having an oxide semiconductor device.

2. Description of the Background

Generally, a bottom gate type thin film transistor includes a gate electrode formed on a substrate, a gate insulation layer formed on the gate electrode, a source electrode and a drain electrode formed on the gate insulation layer, and an active layer disposed between the source electrode and the drain electrode.

The active layer usually includes a semiconductor material such as amorphous silicon or polysilicon. However, when the active layer includes amorphous silicon, the thin film transistor may not have a desired high response speed because of the active layer's low charge mobility. When the active layer includes polysilicon, the thin film transistor may require an additional compensating circuit because of irregular threshold voltage thereof even though the thin film transistor has relatively high charge mobility.

When a thin film transistor is obtained by a low temperature polysilicon (LTPS) process, an expensive process such as a laser annealing process may be required in manufacturing the thin film transistor, so that manufacturing and maintaining cost for the thin film transistor may be increased. Additionally, such a thin film transistor may not be properly used in a large display device.

To solve the above-mentioned problems, an oxide thin film transistor has been developed to have an active layer of semiconductor oxide such as zinc oxide (ZnOx). In a method of forming the oxide thin film transistor having the semiconductor oxide active layer, a metal layer for forming a source electrode and a drain electrode is formed on a gate insulation layer. Then, the metal layer is patterned by an etching process to form the source electrode and the drain electrode on the gate insulation layer.

However, damage may be easily generated at a surface of the gate insulation layer is while patterning the metal layer for forming the source and the drain electrodes. Additionally, the gate insulation layer may be frequently contaminated by etched by-products generated while etching the metal layer. The damaged and contaminated gate insulation layer may deteriorate electrical characteristics of the oxide thin film transistor such as increased distribution of threshold voltages, reduced charge mobility, etc. Furthermore, the oxide thin film transistor may have poor reliability because of the damaged and contaminated gate insulation layer.

### SUMMARY

Example embodiments provide an oxide semiconductor device including a channel protection structure among a gate insulation layer, a source electrode, and a drain electrode to prevent damage to an interface between the gate insulation layer and an active pattern while preventing contaminations of the interface.

Example embodiments provide a method of forming an oxide semiconductor device having a channel protection structure among a gate insulation layer, a source electrode, and a drain electrode to prevent damage to an interface between the gate insulation layer and an active pattern while preventing contaminations of the interface.

Example embodiments provide a display device including an oxide semiconductor device having a channel protection structure to improve display speed of images while reducing a size thereof.

According to example embodiments, there is provided an oxide semiconductor device having a gate electrode, a gate insulation layer, a channel protection structure, a source electrode, a drain electrode, and an active pattern. The gate electrode may be disposed on a substrate, and a gate insulation layer may be disposed on the gate electrode. The channel is protection structure may be positioned on the gate insulation layer to expose a portion of the gate insulation layer. The source electrode may be located on a first portion of the channel protection structure. The drain electrode may be disposed on a second portion of the channel protection structure. The active pattern may be positioned on an exposed portion of the gate insulation layer, the source electrode, and the drain electrode.

According to example embodiments, there is provided a method of manufacturing an oxide semiconductor device. In the method, a gate electrode may be formed on a substrate. A gate insulation layer may be formed on the gate electrode. A channel protection structure may be formed on the gate insulation layer to expose a portion of the gate insulation layer. A source electrode may be formed on a first portion of the channel protection layer. A drain electrode may be formed on a second portion of the channel protection layer. An active pattern may be formed on an exposed portion of the gate insulation layer, the source electrode, and the drain electrode.

According to example embodiments, there is provided a display device including an oxide semiconductor device disposed on a substrate, a first electrode electrically connected to the oxide semiconductor device, a light emitting layer disposed on the first electrode, and a second electrode disposed on the light emitting layer. The oxide semiconductor device may include a gate electrode disposed on the substrate, a gate insulation layer disposed on the gate electrode, a channel protection structure disposed on the gate insulation layer to expose a portion of the gate insulation layer, the channel protection structure having a first protection pattern disposed on a first portion of the gate insulation layer and a second protection pattern disposed on a second portion of the gate insulation layer, a source electrode disposed on the first protection pattern, a drain electrode disposed on the second protection pattern, and an active is pattern disposed on the source electrode, the drain electrode, and an exposed portion of the gate insulation layer. The first electrode may be electrically connected to the drain electrode.

According to example embodiments, there is provided a semiconductor device including a first electrode disposed on a substrate and an insulating layer disposed on the first electrode. A protection structure is disposed on the insulating layer while exposing a portion of the insulating layer. A second electrode is disposed on a first portion of the protection structure, and a third electrode is disposed on a second portion of the protection structure. An active layer is disposed directly on the exposed portion of the insulating layer, the first portion of the protection structure, the second portion of the protection structure, the second electrode, and the third electrode.

According to example embodiments, the oxide semiconductor device may include the channel protection structure among the gate insulation layer, the source electrode and the drain electrode, so that damage to the gate insulation layer may be prevented and reaction by-products including metal compounds remaining between the gate insulation layer and the active pattern may be removed while forming the source electrode and the drain electrode. Therefore, a channel region generated in the active pattern of the oxide semiconductor device may be level and uniform, thereby ensuring improved electrical characteristics of the oxide semiconductor device, for example, an improved operation current, a reduced distribution of threshold voltages, an increased charge mobility in the channel region, etc. When the oxide semiconductor device is used in a display device such as an organic light emitting display device or a flexible display device, the display may have a reduced thickness and may ensure enhanced image display speed.

### BRIEF DESCRIPTION OF THE DRAWINGS

The accompanying drawings, which are included to provide a further understanding of the invention and are incorporated in and constitute a part of this specification, illustrate example embodiments of the invention, and together with the description serve to explain the principles of the invention.

FIG. 1 is a cross-sectional view illustrating an oxide semiconductor device in accordance with example embodiments.

FIG. 2, FIG. 3, and FIG. 4 are cross-sectional views illustrating a method of forming an oxide semiconductor device in accordance with example embodiments.

FIG. 5 is a cross-sectional view illustrating an oxide semiconductor device in accordance with some example embodiments.

FIG. 6, FIG. 7, and FIG. 8 are cross-sectional views illustrating a method of manufacturing an oxide semiconductor device in accordance with some example embodiments.

FIG. 9 is a cross-sectional view illustrating a display device having an oxide semiconductor device in accordance with example embodiments.

### DESCRIPTION OF EMBODIMENTS

Various example embodiments will be described more fully hereinafter with reference to the accompanying drawings, in which some example embodiments are shown. The invention may, however, be embodied in many different forms and should not be construed as limited to example embodiments set forth herein. Rather, these example embodiments are provided so that this description will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. It will be understood that for the purposes of this disclosure, “at least one of . . . and” will be interpreted to mean any combination the enumerated elements following the respective language, including combination of multiples of the enumerated elements. For example, “at least one of X, Y, and Z” will be construed to mean X only, Y only, Z only, or any combination of two or more items X, Y, and Z (e.g. XYZ, XZ, YZ).

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in is use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some is implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

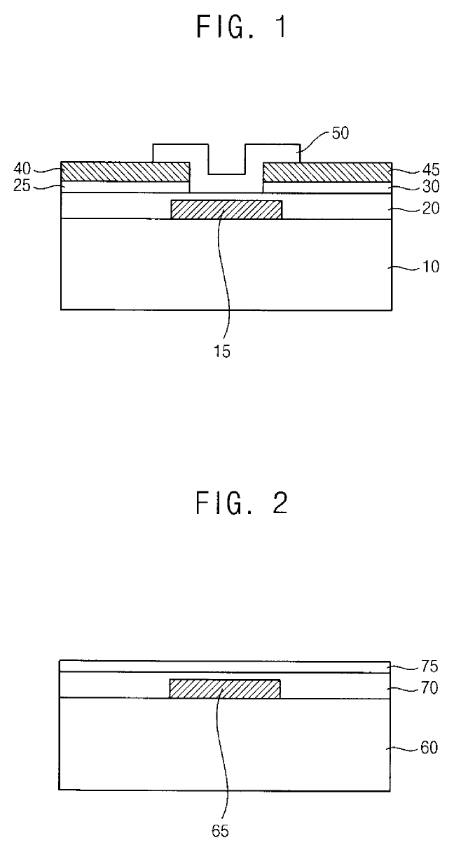

FIG. 1 is a cross-sectional view illustrating an oxide semiconductor device in accordance with example embodiments.

Referring to FIG. 1, the oxide semiconductor device may include a gate electrode 15, a gate insulation layer 20, a channel protection structure, a source electrode 40, a drain electrode 45, and an active pattern 50.

The gate electrode 15 may be disposed on a substrate 10, and the gate insulation layer 20 may be positioned on the substrate 10 to substantially cover the gate electrode 15. In example embodiments, the channel protection structure may expose a portion of the gate insulation layer 20. That is, a portion of the gate insulation layer 20 under which the gate electrode 15 is located may be exposed by the channel protection structure. The source electrode 40 and the drain electrode 45 may be disposed on a first portion of the channel protection structure and a second portion of the channel protection structure, respectively. The channel protection structure may include a first protection pattern 25 and a second protection pattern 30. In this case, the first protection pattern 25 and the second protection pattern 30 may correspond to the first portion of the channel protection structure and the second portion of the channel protection structure, respectively. As described above, the first protection pattern 25 and the second protection pattern 30 may be respectively arranged on a first portion of the gate insulation layer 20 and a second portion of the gate insulation layer 20 to thereby expose the portion of the gate insulation layer 20 positioned on the gate electrode 15.

The first protection pattern 25 of the channel protection structure may be located between the first portion of the gate insulation layer 20 and the source electrode 40. The second protection pattern 30 may be positioned between the second portion of the gate insulation layer 20 and the drain electrode 45. The active pattern 50 may be disposed between the source electrode 40 and the drain electrode 45 to make contact with the gate insulation layer 20. That is, the active pattern 50 may contact the portion of the gate insulation layer 20 exposed by channel protection structure.

The substrate 10 may include a transparent insulation substrate, for example, a glass substrate, a plastic substrate, a metal oxide substrate, etc. In example embodiments, the gate electrode 15 may be connected to a gate line (not illustrated) provided on the substrate 10. Here, the oxide semiconductor device may be turned on and off by a gate on/off voltage applied to the gate electrode 15 through the gate line.

In example embodiments, the gate electrode 15 may include metal, alloy, metal nitride, a transparent conductive material, etc. For example, the gate electrode 15 may include aluminum (Al), alloy of aluminum, aluminum nitride (AlNx), silver (Ag), alloy of silver, tungsten (W), tungsten nitride (WNx), copper (Cu), alloy of copper, nickel (Ni), chrome (Cr), molybdenum (Mo), alloy of molybdenum, titanium (Ti), titanium nitride (TiNx), platinum (Pt), is tantalum (Ta), neodymium (Nd), scandium (Sc), tantalum nitride (TaNx), zinc oxide (ZrOx), indium tin oxide (ITO), tin oxide (SnOx), indium oxide (InOx), gallium oxide (GaOx), indium zinc oxide (IZO), etc. These may be used alone or in any combination thereof. The gate electrode 15 may have a single layer structure including a metal film, an alloy film, a metal oxide film, or a metal nitride film. In some example embodiments, the gate electrode 15 may have a multi layer structure including a metal film, an alloy film, a metal oxide film, and/or a metal nitride film.

In accordance with example embodiments, when the gate electrode 15 includes the transparent conductive material, the oxide semiconductor device may be used in a flexible display device having a relatively thin thickness because substantially all of the elements in the oxide semiconductor device may include transparent materials.

Generally, a gate electrode of a thin film transistor (TFT) may include metal having a relatively low resistance, for example, aluminum, silver, copper, etc. However, such metal may have disadvantages such as a relatively low thermal resistance, a relatively low corrosion resistance, etc. Considering such problems, the gate electrode 15 may include a combination of a first metal having a relatively high electrical conductivity and a second metal having a relatively high thermal resistance. In example embodiments, the gate electrode 15 may have a multi layer structure that has a first metal layer having a relatively low resistance, a second metal layer having a relatively high thermal resistance and/or a metal compound layer having a relatively high thermal resistance. For example, the first metal layer may include aluminum, silver, copper, etc., and the second metal layer may include molybdenum, titanium, chrome, tantalum, tungsten, neodymium, scandium, etc. Additionally, the metal compound layer may include nitrides containing molybdenum, titanium, chrome, tantalum, tungsten, neodymium, scandium, etc. For example, the gate electrode 15 may have a multi layer structure that includes a combination of various layers such as an aluminum layer and a molybdenum layer, a silver layer and a molybdenum layer, a copper layer and a molybdenum layer, a copper layer and a titanium nitride layer, a copper layer and a tantalum nitride layer, a titanium nitride layer and a molybdenum layer, and the like. In some example embodiments, the gate electrode 15 may have a multi layer structure that includes a first metal layer including at least one first metal having a relatively high electrical conductivity, a second metal layer including at least one second metal having a relatively high thermal resistance, and/or a metal compound layer including at least one metal compound having a relatively high thermal resistance.

The gate insulation layer 20 may be disposed on the substrate to cover the gate electrode 15. In example embodiments, the gate insulation layer 20 may have a substantially level upper face without a stepped portion adjacent an upper portion of the gate electrode 15 while the gate insulation layer 20 sufficiently covers the gate electrode 15. In other words, the gate insulation layer 20 may be a planarizing layer. The gate insulation layer 20 may include a silicon compound, metal oxide, etc. For example, the gate insulation layer 20 may include silicon oxide (SiOx), silicon nitride (SiNx), silicon oxynitride (SiOxNy), aluminum oxide (AlOx), tantalum oxide (TaOx), hafnium oxide (HfOx), zirconium oxide (ZrOx), titanium oxide (TiOx), etc. These may be used alone or in any combination thereof. The gate insulation layer 20 may include a single layer structure or a multi layer structure including silicon compound and/or metal oxide. Additionally, the gate insulation layer 20 may have a relatively large thickness. For example, the gate insulation layer 20 may have a thickness of about 50 nm to about 300 nm when measured from an upper face of the substrate 10.

Referring now to FIG. 1, the channel protection structure may be disposed on the is gate insulation layer 20 to expose a portion of the gate insulation layer 20. For example, the first protection pattern 25 and the second protection pattern 30 of the channel protection structure may be positioned on the gate insulation layer 20 by a predetermined distance centering the gate electrode 15. Each of the first protection pattern 25 and the second protection pattern 30 may have a uniform thickness. In this case, the distance between the first protection pattern 25 and the second protection pattern 30 may be smaller than a width of the gate electrode 15. In example embodiments, the first protection pattern 25 may be separated from the second protection pattern 30 so that the portion of the gate insulation layer 20 may be exposed between the first protection pattern 25 and the second protection pattern 30. Here, the first protection pattern 25 and the second protection pattern 30 may have smaller sizes than that of the gate insulation layer 20. Further, the first protection pattern 25 and the second protection pattern 30 may partially overlap the gate electrode 15. For example, end portions of the first and the second protection patterns 25 and 30 may extend to overlap portions of the gate insulation layer 20 under which end portions of the gate electrode 15 are positioned.

In example embodiments, each of the first protection pattern 25 and the second protection pattern 30 may have a relatively small thickness in a range of about 10 Å to about 500 Å measured from an upper face of the gate insulation layer 20. Thus, a thickness ratio of the gate insulation layer 20 to each of the first and the second protection patterns 25 and 30 may be in a range of about 1.0:0.003 to about 1.0:1.0. However, the thickness ratio between the gate insulation layer 20 and one of the first and the second protection patterns 25 and 30 may vary according to dimensions of the oxide semiconductor device, required electrical characteristics of the oxide semiconductor device, etc.

In example embodiments, the first and the second protection patterns 25 and 30 is may each include transparent semiconductor oxides. Examples of the transparent semiconductor oxides may include indium-gallium-zinc oxide (IGZO), gallium zinc oxide (GZO), indium tin oxide (ITO), indium zinc oxide (IZO), zinc oxide (ZnOx), tin oxide (SnOx), indium oxide (InOx), gallium oxide (GaOx), etc. In some example embodiments, the first and the second protection patterns 25 and 30 may include semiconductor oxide doped with copper (Cu), germanium (Ge), antimony (Sb), bismuth (Bi), etc. These may be used alone or in any combination thereof.

In some example embodiments, each of the first and the second protection patterns 20 and 30 may include an insulation oxide. Examples of the insulation oxide may include silicon oxide (SiOx), hafnium oxide (HfOx), zirconium oxide (ZrOx), tantalum oxide (TaOx), etc. These may be used alone or in any combination thereof.

In some example embodiments, each of the first and the second protection patterns 25 and 30 may have a multi-layered structure that includes a transparent semiconductor oxide and an insulation oxide.

As illustrated in FIG. 1, the source electrode 40 may be disposed on the first protection pattern 25, and the drain electrode 45 may be disposed on the second protection pattern 30. The source electrode 40 and the drain electrode 45 may have sizes substantially the same as or substantially similar to those of the first protection pattern 25 and the second protection pattern 30, respectively. In example embodiments, the source electrode 40 and the drain electrode 45 may have substantially level upper faces without any stepped portions caused by a structure of the gate insulation layer 20. The source electrode 40 may be electrically connected to a data line (not illustrated) positioned over the gate line, and the drain electrode 45 may be electrically connected to a pixel electrode (not illustrated) of a display device. In this case, the data line may extend in a second direction substantially perpendicular to the gate line, and the pixel electrode may be disposed in a pixel region defined by the gate line and the data line, which intersect each other along a substantially perpendicular direction.

In example embodiments, each of the source and the drain electrodes 40 and 45 may include metal, alloy and/or metal nitride. For example, the source and the drain electrodes 40 and 45 may include aluminum, copper, molybdenum, titanium, tantalum, tungsten, neodymium, scandium, alloy of these metals, nitride of these metals, etc. These may be used alone or in any combination thereof. In some example embodiments, the source and the drain electrodes 40 and 45 may each include transparent conductive materials. For example, the source and the drain electrodes 40 and 45 may include indium tin oxide, indium zinc oxide, zinc oxide, tin oxide, carbon nanotubes, etc. These may be used alone or in any combination thereof.

According to example embodiments, the source and the drain electrodes 40 and 45 may be formed using conductive materials having low resistances such as aluminum or copper considering electrical characteristics of the oxide semiconductor device. However, the conductive material of a low resistance may have a relatively low thermal resistance or a relatively low corrosion resistance. Thus, the source and the drain electrodes 40 and 45 may be formed using materials having thermal resistances besides the conductive materials. Examples of such material may include molybdenum, titanium, chrome, tantalum, tungsten, neodymium, scandium, etc. These may be used alone or in any combination thereof. Each of the source and the drain electrodes 40 and 45 may have a multi-layered structure. For example, each of the source and the drain electrodes 40 and 45 may have a multi layer structure that includes a first conductive layer containing a material having a thermal resistance material, a second conductive layer containing a material having a low resistance, and a third conductive layer containing a is material having a thermal resistance. When the source and the drain electrodes 40 and 45 have the above-described multi layer structure, the source and the drain electrodes 40 and 45 may have relatively low resistances caused by the conductive materials, and also hillocks in the source and the drain electrodes 40 and 45 may be prevented in accordance with existences of the materials having thermal resistances. In some example embodiments, the source and the drain electrodes 40 and 45 may have various structures, for example, single layer structures, double layer structures, triple layer structures, quadruple layer structures, etc., which include a conductive material and/or a thermally resistive material.

Referring again to FIG. 1, the active pattern 50 may be disposed on the source electrode 40, the drain electrode 45, and the gate insulation layer 20. In example embodiments, the active pattern 50 may be positioned on a portion of the source electrode 40, a portion of the drain electrode 45, and the portion of the gate insulation layer 20 exposed between the source and the drain electrodes 40 and 45. In this case, sidewalls of the first protection pattern 25 and the source electrode 40 may make contact with a first lateral portion of the active pattern 50. Further, sidewalls of the second protection pattern 30 and the drain electrode 45 may contact a second lateral portion of the active pattern 50. Additionally, a first end portion of the active pattern 50 may extend on the source electrode 40, and a second end portion of the active pattern 50 may extend on the drain electrode 45. Thus, the first and the second end portions of the active pattern 50 may overlap and extend beyond both end portions of the gate electrode 15, respectively. Since the active pattern 50 may be disposed on the source electrode 40, the drain electrode 45, and the gate insulation layer 20, the active pattern 50 may have stepped portions adjacent to both of the end portions of the active pattern 50. For example, the active pattern 50 may have a substantially “U” shape cross section that includes stepped portions adjacent to both is of the end portions thereof.

In example embodiments, the active pattern 50 may include a semiconductor oxide. For example, the active pattern 50 may include amorphous indium-gallium-zinc oxide (IGZO), gallium zinc oxide (GZO), indium tin oxide (ITO), indium zinc oxide (IZO), zinc oxide, gallium oxide, tin oxide, indium oxide, etc. These may be used alone or in any combination thereof. The active pattern 50 may have a single layer structure or a multi layer structure including transparent semiconductor oxide. As described above, when each of the first protection pattern 25 and the second protection pattern 30 includes a semiconductor oxide, the active pattern 50 may include a semiconductor oxide that is substantially the same as or substantially similar to that of the first protection pattern 25 or the second protection pattern 30. Alternatively, each of the first and the second protection patterns 25 and 30 may include a semiconductor oxide that is substantially different from that of the active pattern 50.

According to example embodiments, oxide semiconductor devices having channel protection structures are illustratively described. However, the channel protection structure according to example embodiments may be used in another thin film transistor including an active pattern (area) of amorphous silicon, polysilicon, partially crystallized silicon, micro crystalline silicon, etc. In this case, the thin film transistor may have a construction substantially the same as or substantially similar to that of the oxide semiconductor device described with reference to FIG. 1 except for materials in the active pattern (area).

According to example embodiments, the first and the second protection patterns 25 and 30 of the channel protection structure may be disposed beneath the source and the drain electrodes 40 and 45, respectively. Therefore, damage to the gate insulation layer 20 may be prevented and reaction by-products containing metal compounds may not remain between the is gate insulation layer 20 and the active pattern 50. Consequently, a channel region of the oxide semiconductor device generated in the active pattern 50 may be substantially regular and level, and also the oxide semiconductor device may have enhanced electrical characteristics, such as, for example, an increased operation current, a reduced distribution of threshold voltages, an increased charge mobility in the channel region, etc.

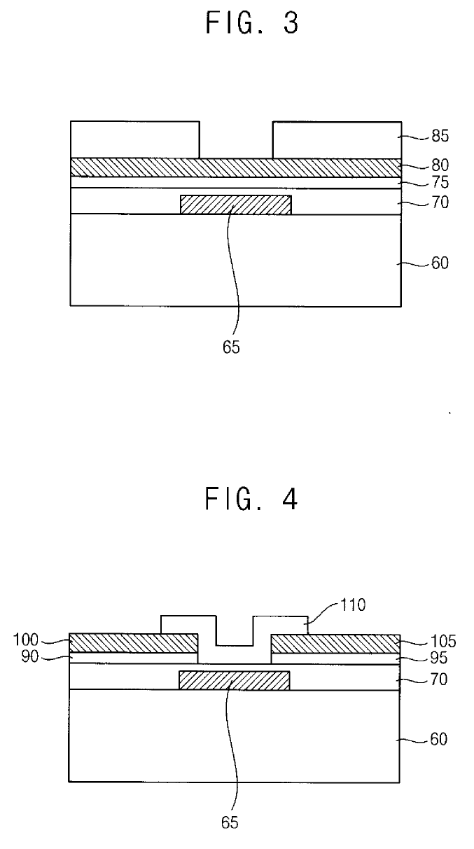

FIGS. 2 to 4 are cross-sectional views illustrating a method of manufacturing an oxide semiconductor device in accordance with example embodiments. In FIGS. 2 to 4, the method may provide an oxide semiconductor device having a construction substantially the same as or similar to that of the oxide semiconductor device described with reference to FIG. 1, however, the method illustrated in FIGS. 2 to 4 may be used in manufacturing other oxide semiconductor devices having various constructions including active patterns, source electrodes, drain electrodes, channel protection structures, etc.

Referring to FIG. 2, a gate electrode 65 may be formed on a substrate 60 including a transparent insulation material such as glass, plastic, ceramic, etc. For example, the gate electrode 65 may be obtained by patterning a first conductive layer (not illustrated) after forming the first conductive layer on the substrate 60 by a sputtering process, a chemical vapor deposition (CVD) process, an atomic layer deposition (ALD) process, a vacuum evaporation process, a printing process, etc. In this case, a gate line (not illustrated) may be formed on the substrate 60 while forming the gate electrode 65. For example, the gate line may extend on the substrate 60 in a first direction, and the gate electrode 65 may extend from the gate line along a direction substantially perpendicular to the first direction.

In example embodiments, the gate electrode 65 may be formed using aluminum, tungsten, copper, nickel, chrome, molybdenum, silver, tantalum, alloy of these metals, nitride of is these metals, etc. These may be used alone or in any combination thereof. Further, the gate electrode 65 may have a single layer structure or a multi layer structure. For example, the gate electrode 65 may have a single layer structure or a multi layer structure including an electrically conductive material and/or a thermally resistive material.

In some example embodiments, the gate electrode 65 may be obtained by patterning a transparent conductive material after depositing the transparent conductive material on the substrate 60. Examples of the transparent conductive material may include indium tin oxide (ITO), indium zinc oxide (IZO), zinc oxide, tin oxide, gallium oxide, indium oxide, etc. These may be used alone or in any combination thereof.

In some example embodiments, a buffer layer (not illustrated) may be formed on the substrate 60, and then the gate electrode 65 may be formed on the buffer layer. Here, the buffer layer may have a single layer structure or a multi layer structure that includes silicon oxide and/or silicon nitride.

A gate insulation layer 70 may be formed on the substrate 60 to cover the gate electrode 65. For example, the gate insulation layer 70 may be obtained by a chemical vapor deposition process, a thermal oxidation process, a plasma enhanced chemical vapor deposition (PECVD) process, a high density plasma-chemical vapor deposition (HDP-CVD) process, a spin coating process, etc. Additionally, the gate insulation layer 70 may be formed using an oxide. For example, the gate insulation layer 70 may be formed using silicon oxide, hafnium oxide, zirconium oxide, aluminum oxide, tantalum oxide, etc. These may be used alone or in any combination thereof.

In example embodiments, the gate insulation layer 70 may have a relatively large thickness considering a transmittance of light incident into the oxide semiconductor device. For example, the gate insulation layer 70 may have a thickness in a range of about 50 nm to about 300 nm when measured from an upper face of the substrate 60. Further, the gate insulation layer 70 may have a level upper face while sufficiently covering the gate electrode 65. In this case, an upper portion of the gate insulation layer 70 may be planarized by a chemical mechanical polishing (CMP) process and/or an etch-back process.

A channel protection layer 75 may be formed on the gate insulation layer 70. The channel protection layer 75 may prevent damage to the gate insulation layer 70 while forming a source electrode 100 (see FIG. 4) and a drain electrode 105 (see FIG. 4). Additionally, the channel protection layer 75 may prevent contamination of the gate insulation layer 70 caused by reaction by-products containing metal compounds generated in an etching process for forming the source and drain electrodes 100 and 105.

In example embodiments, the channel protection layer 75 may be formed using semiconductor oxide, insulation oxide, etc. For example, the channel protection layer 75 may be formed using indium-gallium-zinc oxide, indium zinc oxide, indium tin oxide, gallium-indium-tin oxide, zinc oxide, tin oxide, gallium oxide, silicon oxide, hafnium oxide, zirconium oxide, etc. These may be used alone or in any combination thereof. In some example embodiments, the channel protection layer 75 may have a multi ingredient composition including semiconductor oxide doped with copper, germanium, antimony, bismuth, etc. These may be added alone or in a combination thereof. Additionally, the channel protection layer 75 may be obtained by a sputtering process, a chemical vapor deposition process, an atomic layer deposition process, a sol-gel process, a vacuum evaporation process, a printing process, a spin coating process, an oxidation process, a plasma enhanced chemical vapor deposition process, a high density plasma-chemical vapor deposition process, etc.

With a conventional method for forming an oxide transistor, a gate insulation layer may be damaged and may be contaminated by etched by-products containing metal compounds in processes for forming a metal layer on the gate insulation layer and for patterning the metal layer to obtain a source electrode and a drain electrode, thereby deteriorating an interface between the gate insulation layer and an active layer formed on the gate insulation layer and damaging a surface of the gate insulation layer. When the interface between the gate insulation layer and the active layer and the surface of the gate insulation layer are damaged, a channel region of the oxide transistor generated in the active layer may be irregular. As a result, a threshold voltage distribution of the oxide transistor may be increased, a charge mobility of the channel region may be reduced, and an operation current of the oxide transistor may be decreased. However, according to example embodiments of the present invention, the channel protection layer 75 may prevent damage and contamination of the gate insulation layer 70 while forming the source and the drain electrodes 100 and 105.

In example embodiments, the channel protection layer 75 may have a relatively small thickness. For example, the channel protection layer 75 may have a thickness in a range of about 10 Å to about 500 Å when measured from an upper face of the gate insulation layer 70. Hence, a thickness ratio of the gate insulation layer 70 to the channel protection layer 75 may be in a range of about 1.0:0.003 to about 1.0:1.0. However, the thickness ratio between the gate insulation layer 70 and the channel protection layer 75 may be increased or decreased in accordance with a size and/or electrical characteristics of the oxide semiconductor device.

Referring to FIG. 3, a second conductive layer 80 may be formed on the channel protection layer 75, and then a photoresist pattern 85 may be formed on the second conductive layer 80. The second conductive layer 80 may be formed using metal, alloy, metal nitride and/or is a transparent conductive material. For example, the second conductive layer 80 may be obtained using aluminum, copper, molybdenum, titanium, chrome, tantalum, tungsten, neodymium, scandium, alloy of these metals, nitride of these metals, indium tin oxide, indium zinc oxide, zinc oxide, tin oxide, carbon nano tube, etc. These may be used alone or in any combination thereof. Additionally, the second conductive layer 80 may be formed by a sputtering process, a printing process, a vacuum evaporation process, a chemical vapor deposition process, an atomic layer deposition process, etc. As described above, the second conductive layer 80 may include a single layer structure or a multi layer structure having metal, alloy, metal nitride, conductive metal oxide, a transparent conductive material, etc.

The photoresist pattern 85 may be formed on the second conductive layer 80 by a photo process. The photoresist pattern 85 may expose a portion of the second conductive layer 80 under which the gate electrode 65 is located. In this case, an area of the exposed portion of the second conductive layer 80 may be smaller than that of the gate electrode 65.

Referring to FIG. 4, the second conductive layer 80 may be etched using the photoresist pattern 85 as an etching mask, so that the source electrode 100 and the drain electrode 105 are formed on the channel protection layer 75. When the source and the drain electrodes 100 and 105 are formed, a portion of the channel protection layer 75 under which the gate electrode 65 is positioned may be exposed. The source and the drain electrodes 100 and 105 may be spaced apart on the channel protection layer 75 by a predetermined distance. The source and the drain electrodes 100 and 105 may overlap with both end portions of the gate electrode 65, respectively. In example embodiments, the channel protection layer 75 may cover the underlying gate insulation layer 70, so that the gate insulation layer 70 may not be damaged in an etching process forming the source and the drain electrodes 100 and 105. Further, reaction by-products containing metal compounds may not remain on the gate insulation layer 70 while forming the source and the drain electrodes 100 and 105.

The exposed portion of the channel protection layer 75 between the source and the drain electrodes 100 and 105 may be etched, such that a first protection pattern 90 and a second protection pattern 95 may be formed beneath the source electrode 100 and the drain electrode 105, respectively. Here, a portion of the gate insulation layer 70 may be exposed between the first protection pattern 90 and the second protection pattern 95. The first and the second protection patterns 90 and 95 may have sizes substantially the same as or substantially similar to those of the source and the drain electrodes 100 and 105, respectively. Further, the portion of the gate insulation layer 70 exposed between the first and the second protection patterns 90 and 95 may have a size smaller than that of the gate electrode 65. In example embodiments, the source and the drain electrodes 100 and 105, and the first and the second protection patterns 90 and 95 may be obtained through different etching processes, respectively. For example, the source and the drain electrodes 100 and 105 may be obtained using a wet etch process, and the first and the second protection patterns 90 and 95 may be obtained using a dry etch process, or vice versa. Alternatively, the source and the drain electrodes 100 and 105 and the first and the second protection patterns 90 and 95 may be obtained using the same type etch process. The photoresist pattern 85 and/or the source and the drain electrodes 100 and 105 may serve as etching masks for forming the first and the second protection patterns 90 and 95. In some example embodiments, etching processes for forming the source and the drain electrodes 100 and 105 and the first and the second protection patterns 90 and 95 may be performed in-situ without any vacuum break.

Referring now to FIG. 4, an active layer (not illustrated) may be formed on the is source electrode 100, the drain electrode 105, and the exposed portion of the gate insulation layer 70 between the first and the second protection patterns 90 and 95. The active layer may have a substantially uniform thickness on the gate insulation layer 70, the source electrode 100, and the drain electrode 105. The active layer may be obtained using semiconductor oxide. Additionally, the active layer may be formed by a sputtering process, a chemical vapor deposition process, an atomic layer deposition process, a vacuum evaporation process, a spin coating process, a sol-gel process, etc. In example embodiments, the active layer may make contact with the exposed portion of the gate insulation layer 70 and a sidewall of the first protection pattern 90, a sidewall of the source electrode 100, a sidewall of the second protection pattern 95, and a sidewall of the drain electrode 105. Therefore, the active layer may have stepped portions adjacent to the source and the drain electrodes 100 and 105 over the gate electrode 65. In some example embodiments, the active layer may be obtained using amorphous silicon, polysilicon, partially crystallized silicon, micro crystalline silicon, etc. These may be used alone or in any combination thereof.

In example embodiments, the active layer may be formed using semiconductor oxide substantially the same as or substantially similar to those of the first and the second protection patterns 90 and 95. For example, when the active layer includes amorphous indium-gallium-zinc oxide, the active layer may be obtained by a sputtering process using a target having a multi component composition containing gallium oxide (GaOx), indium oxide (InOx), and zinc oxide (ZnOx).

As illustrated in FIG. 4, an active pattern 110 may be formed on a portion of the source electrode 100, a portion of the drain electrode 105, and the exposed portion of the gate insulation layer 70 by etching the active layer. For example, the active layer may be etched by a photolithography process. The active pattern 110 may have stepped portions between the gate is insulation layer 70 and the source electrode 100 and between the gate insulation layer 70 and the drain electrode 105 in accordance with the stepped portions of the active layer. Here, the active pattern 110 may directly make contact with the sidewalls of the first protection pattern 90, the second protection pattern 95, the source electrode 100, and the drain electrode 105. Hence, a lower portion of the active pattern 110 may have a size smaller than that of the gate electrode 65, whereas an upper portion of the active pattern 110 may have a size larger than that of the gate electrode 65.

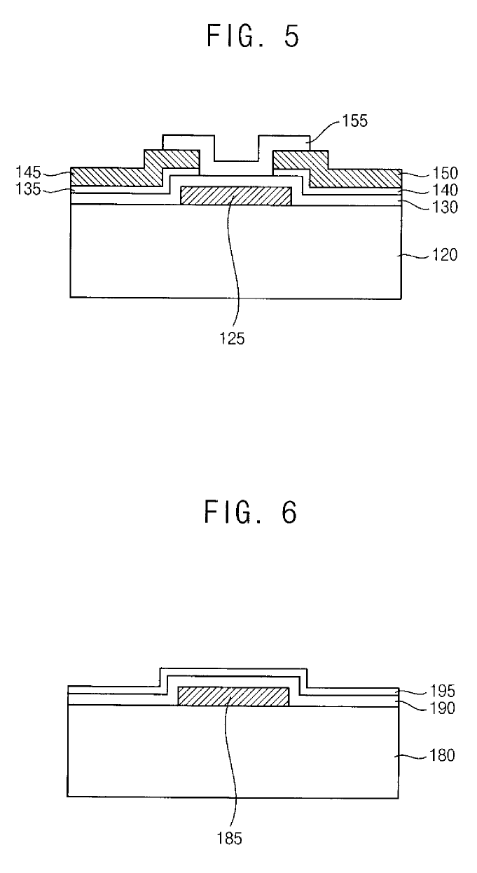

FIG. 5 is a cross-sectional view illustrating an oxide semiconductor device in accordance with some example embodiments.

Referring to FIG. 5, the oxide semiconductor device may be provided on a substrate 120. The oxide semiconductor device may include a gate electrode 125, a gate insulation layer 130, a channel protection structure having a first protection pattern 135 and a second protection pattern 140, a source electrode 145, a drain electrode 150, and an active pattern 155.

The substrate 120 may include a transparent insulation material. The gate electrode 125 may include metal, metal nitride, alloy, a transparent conductive material, etc. A gate line (not illustrated) may be disposed on the substrate 100. The gate line may extend along a first direction and may make contact with the gate electrode 125.

In example embodiments, the gate insulation layer 130 may be disposed on the substrate 120 along a profile of the gate electrode 125. That is, the gate insulation layer 130 may have a uniform thickness on the substrate 120, so that to the gate insulation layer 130 may have a stepped portion adjacent to an end portion of the gate electrode 125. In this case, the gate insulation layer 130 may have a relatively small thickness. Substantially all the elements in the is oxide semiconductor device may have stepped portions in accordance with the stepped portion of the gate insulation layer 130. The gate insulation layer 130 may include silicon oxide and/or metal oxide.

The channel protection structure may be disposed on the gate insulation layer 130 to expose a portion of the gate insulation layer 130. In example embodiments, the channel protection structure may include a first protection pattern 135 and a second protection pattern 140. The first protection pattern 135 and the second protection pattern 140 may be positioned on a first portion of the gate insulation layer 130 and a second portion of the gate insulation layer 130, respectively. Each of the first and the second protection patterns 135 and 140 may have a stepped portion caused by the stepped portion of the gate insulation layer 130. Here, the stepped portions of the first and the second protection patterns 135 and 140 may be adjacent to end portions of the gate electrode 125, respectively. For example, the stepped portion of the first protection pattern 135 may be adjacent to one end portion of the gate electrode 125, and the stepped portion of the second protection pattern 140 may be adjacent to another end portion of the gate electrode 125. Each of the first and the second protection patterns 135 and 140 may include semiconductor oxide, insulation oxide, a transparent conductive material, etc.

The source electrode 145 and the drain electrode 150 may be disposed on the first protection pattern 135 and the second protection pattern 140, respectively. The source and the drain electrodes 145 and 150 may also include stepped portions adjacent to the stepped portions of the first and the second protection patterns 135 and 140, respectively, in accordance with the stepped portion of the gate insulation layer 130. Each of the source and the drain electrodes 145 and 150 may include metal, a conductive metal compound, a transparent conductive metal compound, etc. The source electrode 145 may be electrically connected to a data line (not is illustrated) extending on the gate insulation layer 130 along a second direction, and the drain electrode 150 may be electrically to a pixel electrode (not illustrated) of a display device.

The active pattern 155 may make contact with the exposed portion of the gate insulation layer 130, the source electrode 145, and the drain electrode 150. In example embodiments, the active pattern 155 may be disposed on the gate insulation layer 130 to be connected to sidewalls of the source and the drain electrodes 145 and 150. Here, sidewalls of the first and the second protection patterns 135 and 140 may make contact with the active pattern 155. Therefore, the active pattern 155 may have stepped portions adjacent to both ends of the exposed portion of the gate insulation layer 130. The active pattern 155 may include semiconductor oxide, a conductive metal compound, amorphous silicon, polysilicon, partially crystallized silicon, micro crystalline silicon, etc.

In some example embodiments, the active pattern 155 may extend on the source and the drain electrodes 145 and 155. Here, although not illustrated, the active pattern 155 may have additional stepped portions adjacent to the stepped portions of the source and the drain electrodes 145 and 155, respectively. That is, the active pattern 155 may have double stepped structure.

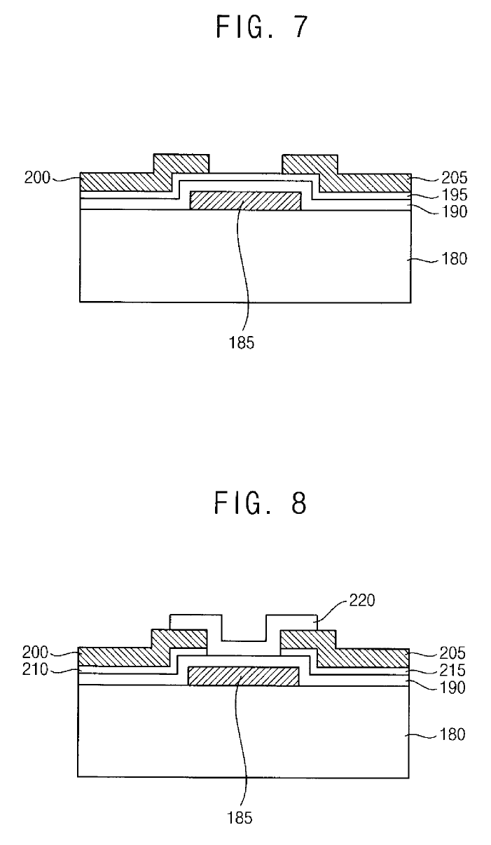

FIGS. 6 to 8 are cross-sectional views illustrating a method of manufacturing an oxide semiconductor device in accordance with some example embodiments. In FIGS. 6 to 8, the method may provide an oxide semiconductor device having a construction substantially the same as or substantially similar to that of the oxide semiconductor device described with reference to FIG. 5. However, the method illustrated in FIGS. 6 to 8 may be used in manufacturing other oxide semiconductor devices having various constructions that include active patterns, source electrodes, drain electrodes, channel protection structures, etc.

Referring to FIG. 6, a gate electrode 185 may be formed on a substrate 180 including a transparent insulation material. In example embodiments, a first conductive layer (not illustrated) may be formed on the substrate 180, and then the first conductive layer may be patterned to form the gate electrode 185. For example, the gate electrode 185 may be formed on the substrate using metal, alloy, metal nitride and/or a transparent conductive material by a sputtering process, a chemical vapor deposition process, an atomic layer deposition process, a vacuum evaporation process, a printing process, etc. In some example embodiments, a buffer layer (not illustrated) may be formed on the substrate 180 before forming the gate electrode 185.

A gate insulation layer 190 may be formed on the substrate 180 to cover the gate electrode 185. The gate insulation layer 190 may be uniformly formed on the substrate 180 along a profile of the gate electrode 185. In example embodiments, the gate insulation layer 190 has a uniform thickness, so that a stepped portion of the gate insulation layer 190 may be generated at a portion of the gate insulation layer 190 adjacent to the gate electrode 185. For example, the gate insulation layer 190 may have stepped portions adjacent to end portions of the gate electrodes 185. The gate insulation layer 190 may be formed using silicon oxide and/or metal oxide to ensure a relatively small thickness.

A channel protection layer 195 may be formed on the gate insulation layer 190. The channel protection layer 195 may be formed on the gate insulation layer 190 using semiconductor oxide, insulation oxide, etc. The channel protection layer 195 having a relatively small thickness may be formed along a profile of the gate insulation layer 190. Thus, the channel protection layer 195 may have stepped portions in accordance with the stepped portions of the gate insulation layer 190. For example, the channel protection layer 195 may have the stepped portions adjacent to the stepped portions of the gate insulation layer 190. The channel is protection layer 195 may prevent an etched damage to the gate insulation layer 190 in a successive etching process, and also the channel protection layer 195 may prevent remaining of reaction by-products containing metal compounds on the gate insulation layer 190.

Referring to FIG. 7, after forming a conductive layer (not illustrated) on the channel protection layer 195, the conductive layer may be partially etched to form a source electrode 200 and a drain electrode 205 on the channel protection layer 195. Each of the source and the drain electrodes 200 and 205 may be formed using metal, alloy, metal nitride, a transparent conductive material, etc. In example embodiments, the source electrode 200 and the drain electrode 205 may be formed on a first portion of the channel protection layer 195 and a second portion of the channel protection layer 195, respectively. By forming the source and the drain electrodes 200 and 205, a portion of the channel protection layer 195 between the source electrode 200 and the drain electrode 205 may be exposed. For example, a portion of the channel protection layer 195 positioned directly over the gate electrode 185 may be exposed. The source and the drain electrodes 200 and 205 may have stepped portions caused by the stepped portions of the gate insulation layer 190. For example, the stepped portions of the source and the drain electrodes 200 and 205 may be adjacent to end portions of the gate electrode 185. Since the gate insulation layer 190 may be protected by the channel protection layer 195 while forming of the source and the drain electrodes 200 and 205, etching damage and contamination of the gate insulation layer 190 may be prevented.

Referring to FIG. 8, the exposed portion of the channel protection layer between the source and the drain electrodes 200 and 205 may be removed to provide a first protection pattern 210 and a second protection pattern 215. Here, a portion of the gate insulation layer 190 may be exposed between the first protection pattern 210 and the second protection pattern 215. For example, the first and the second protection patterns 210 and 215 may be obtained by a dry etching process or a wet etching process.

An active layer (not illustrated) may be formed on the source electrode 200, the drain electrode 205, and the exposed portion of the gate insulation layer 190. An active pattern 220 may be obtained by patterning the active layer. The active pattern 220 may have a uniform thickness on the exposed portion of the gate insulation layer 190, the source electrode 200, and the drain electrode 205. The active pattern 220 may make contact with the exposed portion of the gate insulation layer 190, a sidewall of the first protection pattern 210, a sidewall of the source electrode 200, a sidewall of the second protection pattern 215, and a sidewall of the drain electrode 205. Thus, step portions of the active pattern 220 may be generated adjacent to both ends of the exposed portion of the gate insulation layer 190. Further, although not illustrated, step portions of the active pattern 220 may also be generated adjacent to the stepped portions of the source and the drain electrodes 200 and 205. The active pattern 220 may be formed using semiconductor oxide, amorphous silicon, polysilicon, partially crystallized silicon, silicon including micro crystals, etc.

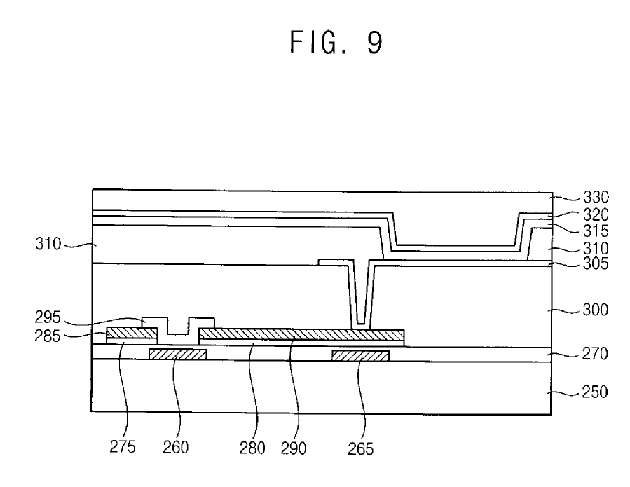

FIG. 9 is a cross-sectional view illustrating a display device having an oxide semiconductor device in accordance with example embodiments. In FIG. 9, the display device may illustratively include a light emitting layer 315. However, the oxide semiconductor device may be used in a liquid crystal display device, a flexible display device, etc. Further, the oxide semiconductor device illustrated in FIG. 9 may have a construction substantially the same as or substantially similar to that of the oxide semiconductor device described with reference to FIG. 1. However, the oxide semiconductor device described with reference to FIG. 5 may be used in the display device illustrated in FIG. 9.

Referring to FIG. 9, an oxide semiconductor device may be provided on a substrate 250. The oxide semiconductor device may include a gate electrode 260, a gate insulation layer 270, a channel protection structure having a first protection pattern 275 and a second protection pattern 280, a source electrode 285, a drain electrode 290, and an active pattern 295.

In example embodiments, a gate line 265 may be provided on the substrate 250. The gate line 265 may be connected with the gate electrode 260. In this case, the gate line 265 may include a material that may be substantially the same as or substantially similar to that of the gate electrode 260. A gate insulation layer 270 may be disposed on the substrate 250 to cover the gate electrode 260 and the gate line 265. The gate insulation layer 270 may have a substantially level upper face. Alternatively, similar to the example embodiment shown in FIG. 5, the gate insulation layer 270 may have stepped portions adjacent to edges of the gate electrode 260 and the gate line 265.

In some example embodiments, a buffer layer (not illustrated) may be disposed between the gate electrode 260 and the substrate 250, and between the gate line 265 and the substrate 250. The buffer layer may prevent diffusion of moisture or impurities, and the gate electrode 260 and the gate line 265 may be relatively easily formed on the substrate 250 because of the buffer layer.

The channel protection structure may be located on the gate insulation layer 270. The source electrode 285 may be disposed on the first protection pattern 275 of the channel protection structure, and the drain electrode 290 may be disposed on the second protection pattern 280 of the channel protection structure. In example embodiments, the second protection pattern 280 and the drain electrode 290 may extend on the gate insulation layer 270 over the gate is line 265. Here, the second protection pattern 280 and the drain electrode 290 may extend along a direction substantially perpendicular a direction where the gate line 265 extends. The active pattern 295 may make contact with a portion of the gate insulation layer 270 between the source and the drain electrodes 285 and 290. The active pattern 295 may be located on the source and the drain electrodes 285 and 290. Here, the active pattern 295 may not be disposed on an extending portion of the drain electrode 290.

An insulation layer 300 may be disposed on the substrate 250 to cover the oxide semiconductor device. The insulation layer 300 may have a substantially flat upper face to improve a light efficiency of a light emitting structure disposed on the insulation layer 300. A hole may be formed through the insulation layer 300 to expose the extending portion of the drain electrode 290. In example embodiments, the insulation layer 300 may include a transparent insulating material. For example, the insulation layer 300 may include acryl-based resin, epoxy resin, phenol resin, polyamide-based resin, polyimide-based resin, unsaturated polyester-based resin, polyphenylene-based resin, polyphenylsulfide-based resin, benzocyclobutene (BCB), etc. These may be used alone or in any combination thereof.

The light emitting structure may be positioned on the insulation layer 300. The light emitting structure may include a first electrode 305, the light emitting layer 315, and a second electrode 320. The first and the second electrodes 305 and 320 may respectively include transparent conductive materials, transflective conductive materials, or reflective conductive materials. The display device may have a top emission type, a bottom emission type, or a dual emission type in accordance with materials included in the first and the second electrodes 305 and 320.

The first electrode 305 of the light emitting structure may serve as a pixel is electrode of the display device. The first electrode 305 of the light emitting structure may be electrically connected with the oxide semiconductor device. In example embodiments, the first electrode 305 of the light emitting structure may make contact with an exposed portion of the drain electrode 290 via the hole in the insulation layer 300. In this case, the first electrode 305 may be disposed on the exposed portion of the drain electrode 290, a sidewall of the hole of the insulation layer 300, and the top surface of the insulation layer 300. In some example embodiments, a contact structure (not illustrated) may be provided in the hole of the insulation layer 300, so that the first electrode 305 may be electrically connected to the drain electrode 290 through the contact structure.

A pixel defining layer 310 may be disposed on the insulation layer 300 to cover the oxide semiconductor device. For example, the pixel defining layer 310 may be positioned on a portion of the insulation layer 300 covering the oxide semiconductor device. In this case, the pixel defining layer 310 may extend to area region in which the drain electrode 290 is electrically connected with the first electrode 305. The pixel defining layer 310 may divide adjacent pixels of the display device. The pixel defining layer 310 may include a transparent insulating material. For example, the pixel defining layer 310 may include polyacryl-based resin, polyimide-based resin, a silica-based inorganic material, etc.

An opening may be formed through the pixel defining layer 310 to expose a portion of the first electrode 305. The light emitting layer 315 and the second electrode 320 of the light emitting structure may be uniformly disposed on the exposed portion of the first electrode 305, a sidewall of the opening, and the top surface of the pixel defining layer 310 along a profile of the opening.

In example embodiments, a plurality of openings of the pixel defining layer 310 is may be provided in a plurality of pixels of the display device. Each of the openings may partially expose each first electrode 305 in each pixel. In this case, the first electrode 305 may be disposed only in the opening of the pixel defining layer 310. Alternatively, the first electrode 305 may extend beneath the pixel defining layer 310, so that the first electrode 305 may be partially overlapped relative to the pixel defined layer 310. As for the display device, a region where the pixel defining layer 310 is positioned may substantially correspond to a non-luminescent region, and another region where the opening of the pixel defining layer 310 is located may substantially correspond to a luminescent region.

The light emitting layer 315 may include a low molecular weight organic material, a high molecular weight organic material, etc. In example embodiments, the light emitting layer 315 may have a multi layer structure that includes an organic light emitting layer, a hole injection layer (HIL), a hole transport layer (HTL), an electron injection layer (EIL), an electron transport layer (ETL), etc. Although not shown in FIG. 9, the light emitting layer 315 may exist in the opening of the pixel defining layer 310 only. However, a position of the light emitting layer 315 may be not limited. For example, as shown in FIG. 9, the light emitting layer 315 may extend on a portion of the pixel defining layer 310 under which the oxide semiconductor device is located.

A protection layer 330 may be disposed on the light emitting structure. In example embodiments, the protection layer 330 may protect underlying structures. The protection layer 330 may also serve as a sealing member of the display device. For example, the protection layer 330 may include a transparent insulating material such as glass, transparent plastic, transparent ceramic, etc.

In example embodiments, a display device may include an oxide semiconductor is device having improved electrical characteristics such as an increased operation current, a reduced threshold voltage distribution, an increased charge mobility in a channel region, etc. Therefore, a thickness of the display device may be reduced, and a resolution of image displayed by the display device may be enhanced. Further, the display device may ensure an improved display speed of image.

According to example embodiments, an oxide semiconductor device may include a channel protection structure to ensure improved electrical characteristics such as an increased operation current, a reduced threshold voltage distribution, an improved of charge mobility in a channel region, etc. When the semiconductor device is used in a display device such as an organic light emitting display device or a flexible display device, the display device may have a reduced thickness, an enhanced resolution of display image, an improved display speed of image, etc.

Although the example embodiments FIGS. 1-9 show edges of the gate electrode, gate insulation layer, and channel protection structure as having 90 degree taper angles, these elements and others may have smaller taper angles, thereby providing a smaller slope, which may help prevent disconnections in the overlying layer.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An oxide semiconductor device, comprising:
a gate electrode disposed on a substrate;
a gate insulation layer disposed on the gate electrode;
a channel protection structure disposed on the gate insulation layer and exposing a portion of the gate insulation layer;
a source electrode disposed on a first portion of the channel protection structure;
a drain electrode disposed on a second portion of the channel protection structure; and
an active pattern disposed on the exposed portion of the gate insulation layer, the source electrode, and the drain electrode.

2. The oxide semiconductor device of claim 1, wherein the gate electrode comprises at least one metal, alloy, metal nitride, and a transparent conductive material.

3. The oxide semiconductor device of claim 1, wherein the gate electrode comprises at least one of a first metal having an electrical conductivity, a second metal having a thermal resistance, and a metal compound having a thermal resistance.

4. The oxide semiconductor device of claim 1, wherein the gate insulation layer has a level upper face or a stepped portion adjacent to the gate electrode.

5. The oxide semiconductor device of claim 4, wherein each of the channel protection structure, the source electrode, and the drain electrode has a level upper face or a stepped portion in accordance with the level upper face or the stepped portion of the gate insulation layer, respectively.

6. The oxide semiconductor device of claim 1, wherein a thickness ratio of the gate insulation layer to the channel protection structure is in a range of about 1.0:0.003 to about 1.0:1.0.

7. The oxide semiconductor device of claim 1, wherein the channel protection structure comprises:
a first protection pattern disposed on a first portion of the gate insulation layer; and
a second protection pattern disposed on a second portion of the gate insulation layer, the second protection pattern being separated from the first protection pattern,
wherein the exposed portion of the gate insulation layer is disposed between the first protection pattern and the second protection pattern.

8. The oxide semiconductor device of claim 7, wherein the source electrode and the drain electrode are disposed on the first protection pattern and the second protection pattern, respectively.

9. The oxide semiconductor device of claim 7, wherein each of the first protection pattern and the second protection pattern comprises a semiconductor oxide.

10. The oxide semiconductor device of claim 9, wherein each of the first protection pattern and the second protection pattern further comprises at least one of copper (Cu), germanium (Ge), antimony (Sb), and bismuth (Bi).

11. The oxide semiconductor device of claim 7, wherein the active pattern, the first protection pattern, and the second protection pattern comprise the same material as each other.

12. The oxide semiconductor device of claim 11, wherein each of the active pattern, the first protection pattern, and the second protection pattern comprises at least one of indium-gallium-zinc oxide (IGZO), gallium-zinc oxide (GZO), indium tin oxide (ITO), indium zinc oxide (IZO), zinc oxide (ZnOx), gallium oxide (GaOx), tin oxide (SnOx), and indium oxide (InOx).

13. The oxide semiconductor device of claim 7, wherein each of the first protection pattern and the second protection pattern comprises an insulation oxide.

14. The oxide semiconductor device of claim 13, wherein each of the first protection pattern and the second protection pattern comprises at least one of silicon oxide (SiOx), hafnium oxide (HfOx), zirconium oxide (ZrOx), and tantalum oxide (TaOx).

15. The oxide semiconductor device of claim 1, wherein the active pattern contacts sidewalls of the source electrode, sidewalls of the drain electrode, and sidewalls of the channel protection structure.

16. The oxide semiconductor device of claim 15, wherein the active pattern has stepped portions adjacent to the sidewalls of the source electrode and the sidewalls of the drain electrode, respectively.

17. A method of manufacturing an oxide semiconductor device, comprising:
forming a gate electrode on a substrate;
forming a gate insulation layer on the gate electrode;
forming a channel protection structure on the gate insulation layer, the channel protection structure exposing a portion of the gate insulation layer;
forming a source electrode on a first portion of the channel protection layer;
forming a drain electrode on a second portion of the channel protection layer; and
forming an active pattern on the exposed portion of the gate insulation layer, the source electrode, and the drain electrode.

18. The method of claim 17, wherein forming the channel protection structure comprises:
forming a channel protection layer on the gate insulation layer; and
etching the channel protection layer to form a first protection pattern on a first portion of the gate insulation layer and to form a second protection pattern on a second portion of the gate insulation layer.

19. The method of claim 18, wherein the channel protection layer is etched after forming the source electrode and the drain electrode.

20. The method of claim 19, wherein forming the active pattern is performed after etching the channel protection layer.
